(19) United States
(12) Patent Application Publication
(10) Pub. No.: US 2015/0243845 A1
(43) Pub. Date: Aug. 27, 2015

(54) LIGHT-EMITTING DEVICE

(71) Applicant: EPISTAR CORPORATION, Hsinchu (TW)

(72) Inventors: Peng-Ren CHEN, Hsinchu (TW); Wen-Ming TSAO, Hsinchu (TW); Chih-Chun KE, Hsinchu (TW)

(73) Assignee: EPISTAR CORPORATION, Hsinchu (TW)

(21) Appl. No.: 14/191,098

(22) Filed: Feb. 26, 2014

(51) Int. Cl. H01L 33/32; H01L 33/06

(52) U.S. Cl. CPC H01L 33/325; H01L 33/06

(57) ABSTRACT

A light-emitting element comprises a light-emitting stacked structure. The light-emitting stacked structure comprises a first type semiconductor layer; an active layer on the first type semiconductor layer; a second type semiconductor layer on the active layer; and a superlattice structure between the active layer and the second type semiconductor layer, comprising a first doped nitride layer and a first undoped nitride layer on the first doped nitride layer.

### TECHNICAL FIELD

The application relates to a light-emitting device, and more particularly, to a light-emitting device composed of nitride semiconductors.

### DESCRIPTION OF BACKGROUND ART

Recently, nitride semiconductors have been widely applied as materials for high bright pure green LEDs and blue LEDs in various light sources such as optical displays, traffic signals, an image scanner and the like. FIG. 1 shows a schematic view of a conventional light-emitting device. A conventional light-emitting device basically includes a growth substrate 10, a buffer layer 12, an n-side semiconductor layer 14, an active layer 16, and a p-side semiconductor layer 18. When imposing a certain level of forward voltage to the p-n junction, holes from the p-side semiconductor layer and electrons from the n-side semiconductor layer are combined in the active layer to release light.

However, due to the high resistivity of nitride semiconductor, the working voltage in light emitting devices is high. It is necessary to improve light emitting devices in order to decrease the forward voltage and extend the lifetime of the light emitting devices. Furthermore, the decrease of forward voltage leads to the decrease of heat generation of the device so the device is more efficient.

### SUMMARY OF THE APPLICATION

The present invention provides a light-emitting element comprising a light-emitting stacked structure. The light-emitting stacked structure comprises a first type semiconductor layer; an active layer on the first type semiconductor layer; a second type semiconductor layer on the active layer; and a superlattice structure between the active layer and the second type semiconductor layer. The superlattice structure comprises a first doped nitride layer and a first undoped nitride layer on the first doped nitride layer.

A light-emitting element comprises a light-emitting stacked structure. The light-emitting stacked structure comprises a first type semiconductor layer; an active layer on the first type semiconductor layer; a second type semiconductor layer on the active layer; and a superlattice structure between the active layer and the second type semiconductor layer. Wherein the superlattice structure comprises a first doped nitride layer; a first undoped nitride layer on the first doped nitride layer; a second doped nitirde layer on the first undoped nitride layer; and a second undoped nitride layer on the second doped nitirde layer, wherein the first undoped nitride layer and the second undoped nitride layer comprise Al_{X}In_{Y}Ga_{(1-X-Y)}N, wherein 0≦X<0.2, 0≦Y<0.05.

### BRIEF DESCRIPTION OF THE DRAWINGS

FIG. 1 illustrates a cross-sectional view of a conventional light-emitting device;

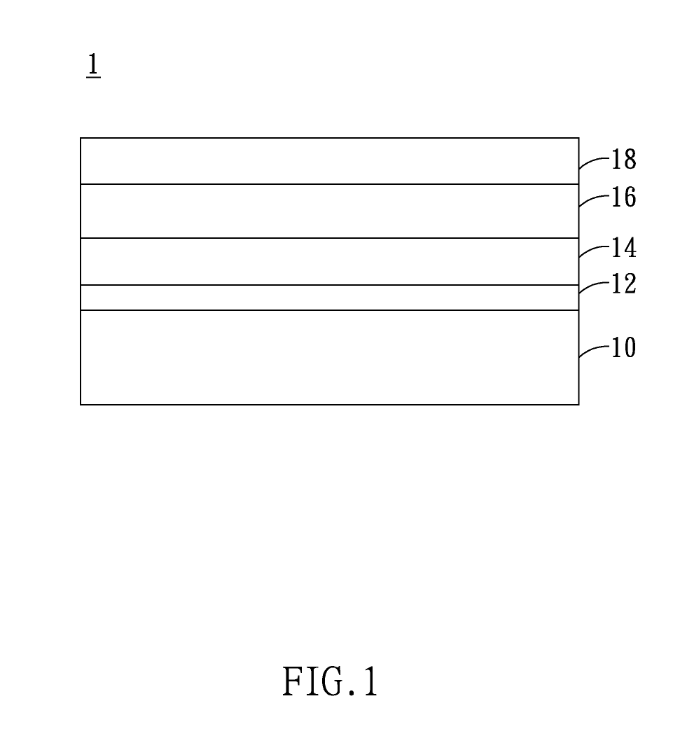

FIG. 2 illustrates a cross-sectional view of a light-emitting device in accordance with one embodiment of the present application;

FIG. 3 illustrates a cross-sectional view of a light-emitting device in accordance with another embodiment of the present application;

### DETAILED DESCRIPTION OF PREFERRED EMBODIMENTS

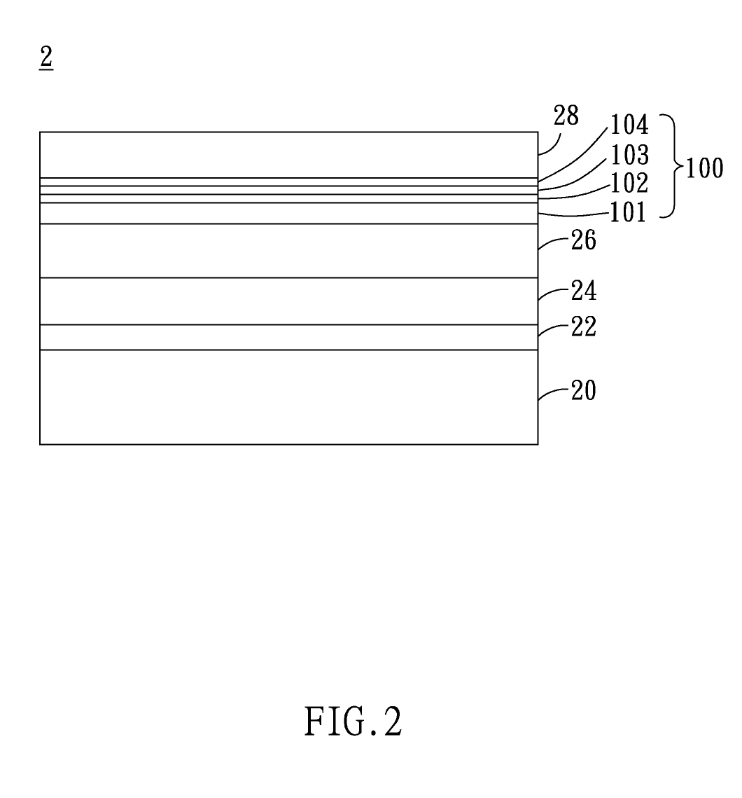

FIG. 2 illustrates a cross-section view of a light-emitting device 2 in accordance with an embodiment of the present application. As shown in FIG. 2, a light-emitting device 2 includes a growth substrate 20 which can be a non-single crystalline substrate or single-crystalline substrate including sapphire, Si, or SiC. A buffer layer 22 is optionally formed on the growth substrate 20 to relax a lattice mismatch between the substrate and the semiconductor layers thereon and improve the crystallized quality. Subsequently, a nitride-based semiconductor stack is formed on the growth substrate 20 by epitaxy process, e.g. metal organic chemical vapor deposition (MOCVD), liquid phase epitaxy (LPE), molecular beam epitaxy (MBE), or the likes. The term nitride refers to any alloy composition of the (Ga, Al, In, B)N semiconductors which can be represented by the formula Al_{X}Ga_{Y}In_{Z}N_{1-A}M_{A} (0≦X≦1, 0≦Y≦1, 0≦Z≦1, and X+Y+Z=1). The symbol M represents a Group V element other than nitrogen (N), 0≦A≦1. The nitride-based compound semiconductor stack comprises a first type semiconductor layer 24, which may be made of GaN, InGaN or AlGaN layer; an active layer 26 laminated on the first type semiconductor layer 24, and comprises one multiple quantum well (MQW) structure; a second type semiconductor layer 28 formed on the active layer 26, wherein the polarities of the first type semiconductor layer 24 and the second type semiconductor layer 28 are different; and a superlattice structure 100 sandwiched between the active layer 26 and the second type semiconductor layer 28. Furthermore, the light-emitting device 2 comprises a first electrode and a second electrode (not shown in FIG. 2) electrically connecting to the first type semiconductor 24 and the second type semiconductor 28, respectively. The superlattice structure 100 comprises a first doped nitride layer 101, a first undoped nitride layer 102, a second doped nitride layer 103, and a second undoped nitride layer 104. In the embodiment, the first doped nitride layer 101 comprises Al_{X}Ga_{(1-X)}N, wherein X ranges between 0.15 and 0.2. The second doped nitride layer 103 comprises In_{Y}Ga_{(1-Y)}N, and Y ranges between 0 and 0.1, preferably 0.02 to 0.03. The polarity of the first doped nitride layer 101 and the second doped nitride layer 103 are the same as that of the second type semiconductor layer 28. For example, when the second type semiconductor layer 28 is a p-type semiconductor, the first doped nitride layer 101 and the second doped nitride layer 103 are doped with p-type impurities such as Mg, Be, Zn or the like. The doping concentrations thereof are from 8×10¹⁸ atoms/cm³ to 8×10¹⁹ atoms/cm³. The thicknesses of first doped nitride layer 101 and second doped nitride layer 103 are both about 5˜200 angstroms. Preferably, the thicknesses of first doped nitride layer 101 and second doped nitride layer 103 is about 40 angstroms and 15 angstroms, respectively. The first undoped nitride layer 102 is sandwiched between first doped nitride layer 101 and second doped nitride layer 103, and the second undoped nitride layer 104 is formed on the second doped nitride layer 103. The material of the first undoped nitride layer 102 and the second undoped nitride layer 104 can be presented as Al_{X}In_{Y}Ga_{(1-X-Y)}N, wherein 0≦X<0.2, 0≦Y<0.05. Furthermore, the first undoped nitride layer 102 and the second undoped nitride layer 104 are substantially undoped or have no intentionally doped impurities. And the thicknesses of the first undoped nitride layer 102 and the second undoped nitride layer 104 are about 10 angstroms.

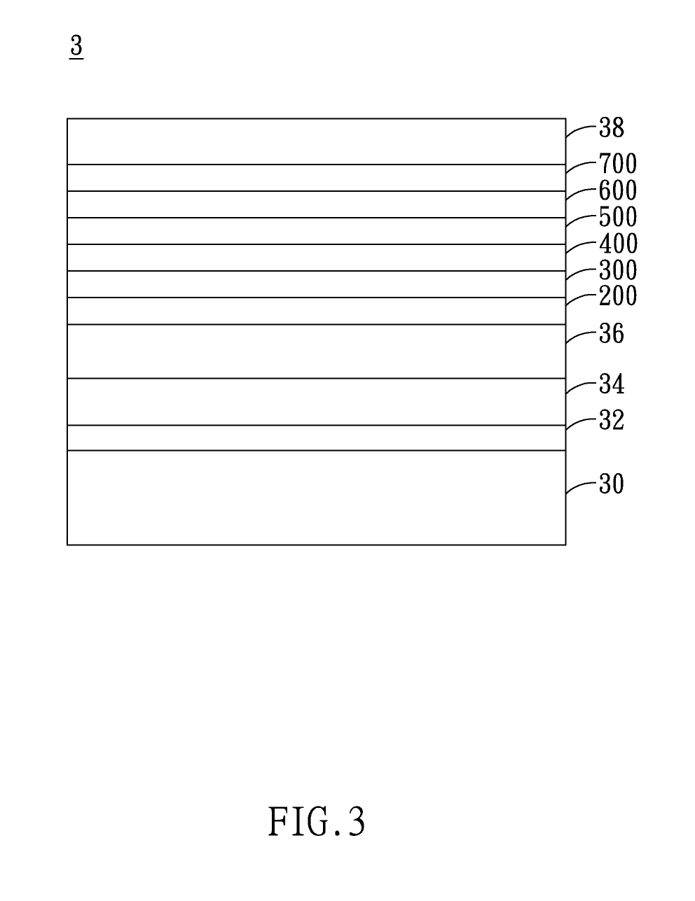

In a conventional nitride light emitting device, the resistivity of the p-type semiconductor layer is high so that the forward voltage in the devices remains high. That is, a higher working voltage is required. In this embodiment, the superlattice structure 100 which comprises the first doped nitride layer 101, the first undoped nitride layer 102, the second doped nitride layer 103 and the second undoped nitride layer 104 stack forms a two-dimensional hole gas. Because of the discontinuity in band gap between the highly-doped nitride material (such as the p-type AlGaN layer or p-type InGaN layer) and the undoped nitride material (such as the u-GaN, the u-InGaN or the u-AlGaN layers), carriers are accumulated in the vicinity of the interface. The movements of the carriers in two dimensions are freer. As a result, the superlattice structure lowers the resistivity and the working voltage of the device, thereby makes it possible to increase the efficiency of the light emitting devices. However, the superlattice structure 100 disclosed in this invention does not limited to the structure described in the embodiment which has the four sub-layers of first doped nitride layer 101, first undoped nitride layer 102, second doped nitride layer 103 and second undoped nitride layer 104. The stack of the first doped nitride layer and the undoped nitride layer which forms a two-dimensional hole gas can also achieve same effects. FIG. 3 is a cross-section view of a light-emitting device 3 in accordance with another embodiment of the present application. The superlattice structure between the active layer 36 and the second type semiconductor layer 38 comprises multiple groups of the first doped nitride layer/first undoped nitride layer/second doped nitride layer/second undoped nitride layer. It is more effective to reduce the resistivity by repeating such group. As illustrated in FIG. 3, the growth substrate 30, the buffer layer 32, the first type semiconductor layer 34, the active layer 36 and the second type semiconductor layer 38 are the same as illustrated in FIG. 2. The superlattice structure comprises six groups of the first doped nitride layer/first undoped nitride layer/second doped nitride layer/second undoped nitride layer 200˜700. These groups are sequentially laminated on the active layer 26 and sandwiched between the active layer 36 and the second type semiconductor layer 38. Each group 200˜700 comprises a structure of first doped nitride layer/first undoped nitride layer/second doped nitride layer/second undoped nitride layer layers as described in FIG. 2. The group disclosed in this embodiment does not limit to the four sub-layers described in the embodiment.

The structure of first doped nitride layer/undoped nitride layer can also be applied. However, when more groups are stacked, the thickness of light emitting devices becomes larger, and the problems of cell cracking and high cost may occur. Therefore, the number of the group is not limited to six but preferred less than twenty. The following table is the experimental comparison of the measured value of forward voltage and light power among different superlattice structures. According to the table, among these different superlattice structures, the structure of Example 1 and Example 2 proposed in the embodiment have the lowest forward voltage Vf. The structure in Example 6 is same as that of Example 1 and Example 2, but the thicknesses of the first u-GaN layer and the second u-GaN layer are 1.5 times thicker.

The Vf in Example 6 is slightly higher than Example 1 and Example 2, but still obviously lower than other supperlattice structures in Example 3˜5. That is, by selecting the supperlattice structure of p-AlGaN/u-GaN/p-InGaN/u-GaN and proper thicknesses of theses layers, the resistivity of the nitride semiconductor is decreased. In short, this superlattice structure helps to accomplish the low working voltage and high performance of light emitting devices.

| Example | Superlattice Structure | Vf (V) | CP % |
|---|---|---|---|
| 1 | p-AlGaN/u-GaN/p-InGaN/u-GaN 1 | 3.16 | 113 |
| 2 | p-AlGaN/u-GaN/p-InGaN/u-GaN 2 | 3.18 | 117 |
| 3 | p-AlGaN/p-InGaN | 3.50 | 106 |
| 4 | p-AlGaN/u-GaN/p-InGaN | 3.27 | 108 |
| 5 | p-AlGaN/p-GaN/p-InGaN/p-GaN | 3.35 | 114 |
| 6 | Same as Example 1 and 2. Thicknesses | 3.21 | 113 |
| | of u-GaN layers × 1.5 | | |

It will be apparent to those having ordinary skill in the art that various modifications and variations can be made to the devices in accordance with the present disclosure without departing from the scope or spirit of the disclosure. In view of the foregoing, it is intended that the present disclosure covers modifications and variations of this disclosure provided they fall within the scope of the following claims and their equivalents.

What is claimed is:

1. A light-emitting element, comprising:
a light-emitting stacked structure comprising:
a first type semiconductor layer;
an active layer on the first type semiconductor layer;
a second type semiconductor layer on the active layer; and
a superlattice structure between the active layer and the second type semiconductor layer, comprising a first doped nitride layer and a first undoped nitride layer on the first doped nitride layer.

2. The light-emitting element of claim 1, wherein the first doped nitride layer comprising AlGaN.

3. The light-emitting element of claim 1, the superlattice structure further comprising a second doped nitride layer on the first undoped nitride layer.

4. The light-emitting element of claim 3, wherein the second doped nitride layer comprising InGaN.

5. The light-emitting element of claim 3, wherein a polarity of the first doped nitride layer is the same as that of the second type semiconductor layer or the second doped nitride layer.

6. The light-emitting element of claim 2, wherein aluminum proportion of the first doped nitride layer is 0.15 to 0.2.

7. The light-emitting element of claim 3, wherein a thickness of the first doped nitride layer is about 40 angstroms.

8. The light-emitting element of claim 3, wherein doping concentration of the first doped nitride layer and the second doped nitride layer are 8×10¹⁸ atoms/cm³ to 8×10¹⁹ atoms/cm³.

9. The light-emitting element of claim 3, wherein a thickness of the second doped nitride layer is about 15 angstroms.

10. The light-emitting element of claim 4, wherein indium proportion of the second doped nitride layer is 0 to 0.1.

11. The light-emitting element of claim 3, wherein the superlattice structure comprising a second undoped nitride layer on the second doped nitride layer.

12. The light-emitting element of claim 11, wherein a thickness of the first undoped nitride layer or the second undoped nitride layer is about 10 angstroms.

13. The light-emitting element of claim 11, wherein the first undoped nitride layer and the second undoped nitride layer comprise undoped Al_{X}In_{Y}Ga_{(1-X-Y)}N, wherein 0≦X≦0.2, 0≦Y≦0.05.

14. The light-emitting element of claim 11, wherein the superlattice structure comprising a plurality of groups of the first doped nitride layer, the first undoped nitride layer, the second doped nitride layer and the second undoped nitride layer sequentially stacked on the active layer.

15. A light-emitting element, comprising:
a light-emitting stacked structure comprising:
a first type semiconductor layer;
an active layer on the first type semiconductor layer;
a second type semiconductor layer on the active layer; and
a superlattice structure between the active layer and the second type semiconductor layer, comprising:
a first doped nitride layer;
a first undoped nitride layer on the first doped nitride layer;
a second doped nitride layer on the first undoped nitride layer; and
a second undoped nitride layer on the second doped nitride layer. wherein the first undoped nitride layer and the second undoped nitride layer comprise Al_{X}In_{Y}Ga_{(1-X-Y)}N, wherein 0≦X≦0.2, 0≦Y≦0.05.

16. The light-emitting element of claim 15, wherein the first doped nitride layer comprising AlGaN, and/or the second doped nitride layer comprising InGaN.

17. The light-emitting element of claim 15, wherein a polarity of the first doped nitride layer is the same as that of the second doped nitride layer.

18. The light-emitting element of claim 15, wherein a polarity of the first doped nitride layer is the same as that of the second type semiconductor layer.

19. The light-emitting element of claim 15, wherein a doping concentration of the first doped nitride layer or the second doped layer is larger than that of the first undoped nitride layer.

20. The light-emitting element of claim 15, wherein a thickness of the first doped nitride layer is larger than that of the second doped nitride layer.
